(19) United States
(12) Patent Application Publication
(10) Pub. No.: US 2015/0008911 A1
(43) Pub. Date: Jan. 8, 2015

(54) APPARATUS FOR SENSING CURRENT FROM ELECTRICAL APPLIANCES

(71) Applicant: Alan Majer, Toronto (CA)

(72) Inventor: Alan Majer, Toronto (CA)

(21) Appl. No.: 14/323,665

(22) Filed: Jul. 3, 2014

Related U.S. Application Data
(60) Provisional application No. 61/843,297, filed on Jul. 5, 2013.

(51) Int. Cl. G01R 19/00; G01R 33/02

(52) U.S. Cl. CPC G01R 19/0092; G01R 33/0206
USPC 324/234

(57) ABSTRACT

Disclosed is an apparatus for sensing current flowing the electric cord of an electric appliance. The electric cord includes at least two current carrying wires. The apparatus includes a current sensing unit, a computing unit, a power source and a housing. The current sensing unit is arranged proximate to the electric cord, the current sensing unit includes a three or more axis sensor operative to detect the changes in magnitude and orientation of magnetic field caused by the current flowing through the current carrying wires of the electric cord for generating an electrical signal. The computing unit is programmed to compute the value of current flowing from the generated electrical signal. The power source is operative to power the current sensing unit. The housing is operative to house the current sensing unit and the power source.

### CROSS REFERENCE RELATED TO APPLICATION

This application claims priority to a U.S. Provisional Application No. 61/843297 filed on Jul. 5, 2014, the entire contents of which are incorporated herein by references in its entirety.

### BACKGROUND OF THE INVENTION

1. Field of the Invention

The present invention generally relates to an apparatus for current measurements, and more particularly relates to an apparatus for sensing current flowing through the electric cord of an electrical appliance.

2. Description of Related Art

Devices have been used to monitor electric current flowing through an electrical cord. Various types of current sensors exist for measuring the intensity of a current flowing through the electrical cord. These sensors provide a magnetic circuit in the shape of a ring around which a secondary winding is wound acting as a magnetic field detector.

Further, the best known sensors in the art sense only a single wire of the electric cord at a time. The isolation of a single wire is often necessary because in a typical power cord, the power travels in both directions generating magnetic fields of equal but opposite strength that tend to cancel each other out. The challenge with many of these sensing systems is that these sensors are often inconvenient and complicated to install. Often, they require separating out a single wire of a circuit in order to take measurements.

For Conventional sensors such as hall-effect sensors used to take measurement from an AC power cord which contains multiple wires, it is often tempting to prescribe strict positioning or arrangements of one or more hall sensors in order to obtain accurate measurements. For conducting such operations the user has to maintain accurate positioning of the sensor or specific sensor arrangements. This leads to be an extra effort and frustration for the user.

Additionally, there is another challenge in measuring the usage of certain devices and appliances that may be switched on by a user, but in fact are consuming little if any power. This is common for electrical appliances such as stoves, coffee makers, and microwaves which cycle power consumption on and off periodically (for example to control the temperature of a heating element) during their use. This poses a problem for any apparatus that wishes to learn the status of an appliance by observing the current consumed in the electrical cord, because the absence of detected electrical current does not always indicate that the appliance is off. Rather, the appliance may just be between power usage cycles during the time that it is in use.

Therefore, there is a need of an apparatus that uses magnetic field sensing principles in one or more dimensions in order to sense current flowing through one or more wire of an electric cord without separating out individual wires. Further, the apparatus should send notification signals to an external device on computing that the current flowing in the electrical cord. Further, the apparatus should observe the on and off cycles of an electrical appliance in order to estimate whether the electrical appliance is likely to be on, regardless of whether there is current sensed at the present time.

### SUMMARY OF THE INVENTION

In accordance with the teachings of the present invention, an apparatus for sensing current flowing through at least one electric cord of an electric appliance is provided.

An object of the present invention is to provide an apparatus for sensing current flowing through the electric cord of an electrical appliance. The electric cord includes at least two current carrying wires. The apparatus includes a current sensing unit arranged proximate to at least one electric cord, a power source to power the current sensing unit and a housing to house the current sensing unit and the power source.

The current sensing unit includes a three or more axis sensor operative to detect the changes in magnitude and orientation of magnetic field caused by the current flowing through in at least two current carrying wires of the electric cord for generating an electrical signal. The current sensing unit further includes a computing unit programmed to compute the value of the current flowing from the generated electrical signal by the three or more axis sensor.

The housing maintains the position of the current sensing unit and the power source to a fixed position in proximity to the electrical cord. In another object of the invention the housing covers the current sensing unit and the power source to protect from the external environment that may disturb their position or working.

The apparatus further includes a visual display unit for displaying the computed value of the current flowing in the electrical cord connected to the computing unit and the power source. The apparatus further includes a notification unit connected to the current sensing unit for producing notifications if the computed value of the current flowing exceeds a pre-stored reference current value.

These and other objects, features and advantages of the invention will become more fully apparent in the following detailed description, taken in conjunction with the accompanying drawings.

### BRIEF DESCRIPTION OF THE DRAWINGS

FIG. 1 illustrates a block diagram of an apparatus for sensing current flowing through an electric cord of an electric appliance, in accordance with a preferred embodiment of the present invention;

FIG. 2 illustrates a perspective view of the apparatus attached to the electrical cord having multiple wires in an exemplary embodiment of the present invention;

FIG. 3 illustrates a graphical representation of detection of the current flowing in the electrical cord; and

FIG. 4 illustrates a perspective view of attachment of housing to the electrical cord of an electrical appliance and transmitting the current value to the notification unit in an exemplary embodiment of the present invention.

The foregoing summary, as well as the following detailed description of certain embodiments of the present invention, will be better understood when read in conjunction with the appended drawings. For the purpose of illustrating the invention, certain embodiments are shown in the drawings. It should be understood, however, that the present invention is not limited to the arrangements and instrumentality shown in the attached drawings.

### DETAILED DESCRIPTION OF DRAWINGS

While this technology is illustrated and described in a preferred embodiment, an apparatus for sensing current flowing through an electric cord of an electric appliance may be produced in many different configurations, forms and materials. There is depicted in the drawings, and will herein be described in detail, as a preferred embodiment of the invention, with the understanding that the present invention is to be considered as an exemplification of the principles of the invention and the associated functional specifications for its construction and is not intended to limit the invention to the embodiment illustrated. Those skilled in the art will envision many other possible variations within the scope of the technology described herein.

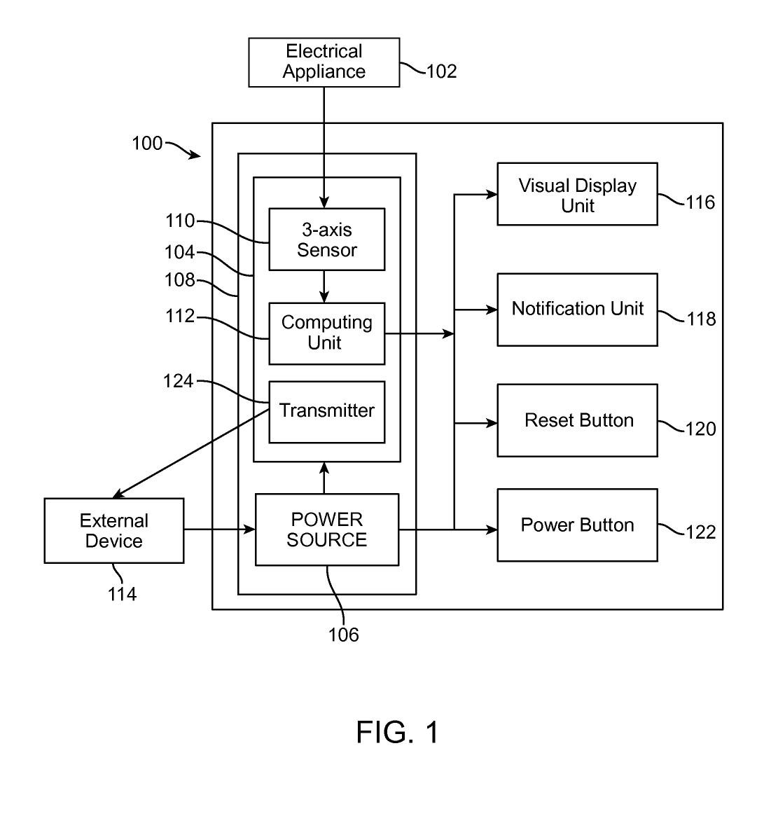

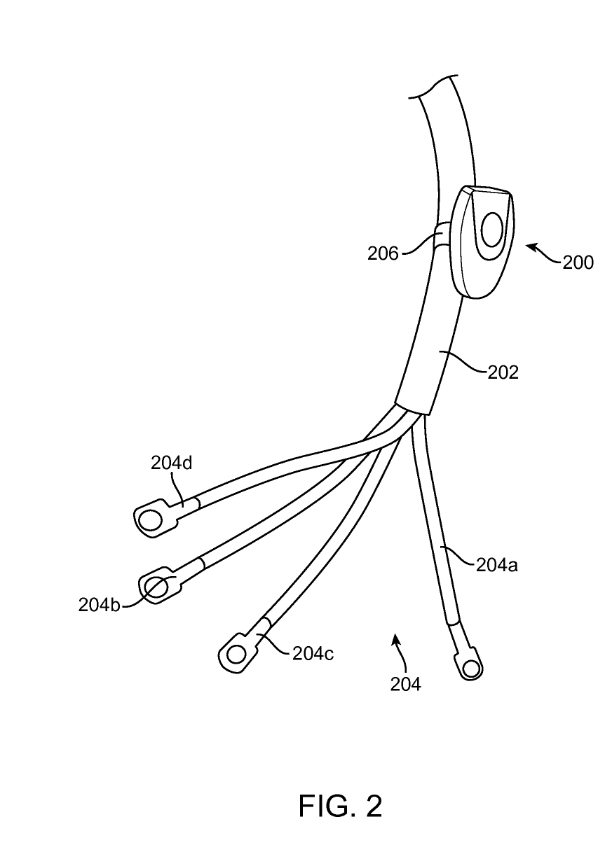

FIG. 1 illustrates a block diagram of an apparatus 100 for sensing current flowing through at least one electric cord of an electrical appliance 102 in a preferred embodiment of the present invention. The electric cord includes at least two current carrying wires. The electric cord is explained in detail in conjunction with FIG. 2 of the present invention. The apparatus 100 includes a current sensing unit 104 arranged proximate to at least one electric cord. In another preferred embodiment of the present invention the current sensing unit further includes a power source 106 to power the current sensing unit 104 and a housing 108 to house the current sensing unit 104 and the power source 106.

The current sensing unit 104 includes at least one three or more axis sensor 110 operative to detect the changes in magnitude and orientation of magnetic field caused by the current flowing through in at least two current carrying wires of the electric cord for generating an electrical signal. In a preferred embodiment of the present invention the three or more axis sensor 110 is a 3-axis magnetometer.

However, it would be readily apparent to those skilled in the art that three separate sensors may be envisioned to achieve the functionality without deviating from the scope of the present invention. Examples of three or more axis sensor 110 include but are not limited to MAG3110, LIS3MDL, HMC5883L etc.

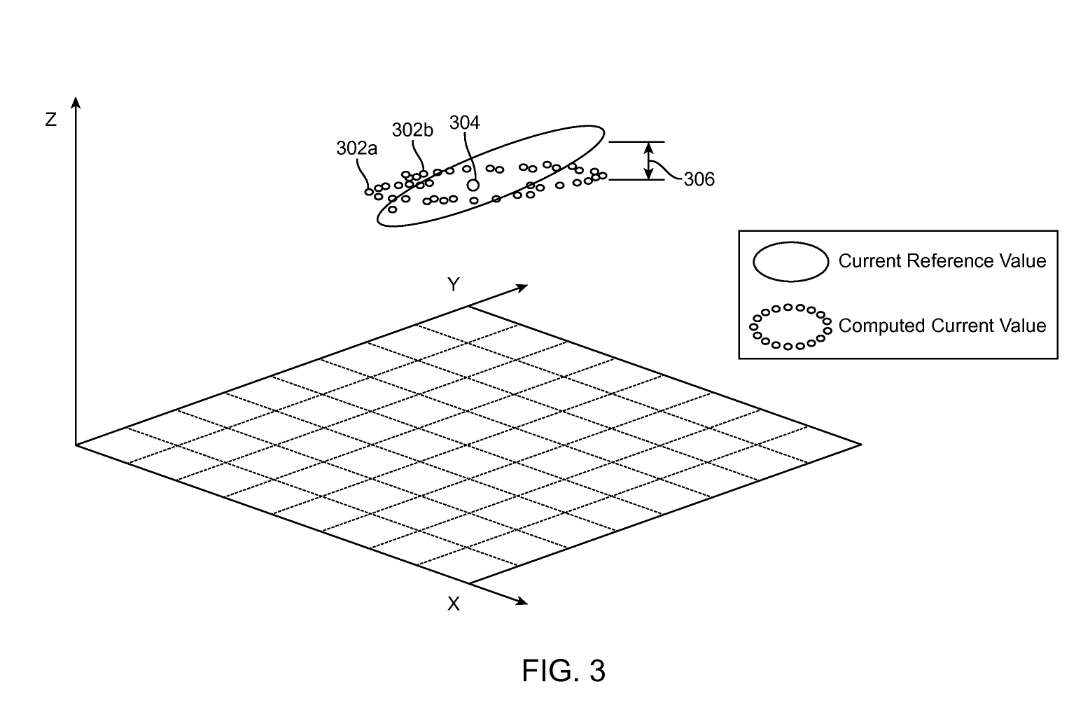

The current sensing unit 104 further includes a computing unit 112 programmed to compute the value of the current flowing from the generated electrical signal by the three or more axis sensor. In a preferred embodiment of the present invention the computing unit 112 is a micro-controller. Examples of the computing unit 112 include processor, microprocessor, microcontroller or any other logic circuit which may perform all the various functions that are desired to be performed by the computing unit 112 as specified in the claims. Examples of methods for calculating the value of the current flowing in the electrical cord is explained with FIG. 3 of the present invention.

The power source 106 powers the current sensing unit 104. In a preferred embodiment of the present invention the power source 106 is a battery. However, it would be readily apparent to those skilled in the art that various type of power source 106 may be envisioned without deviating from the scope of the present invention. In another preferred embodiment of the present invention, the power source 106 may take power from an external device 114 such as wireless chargers or a power adapter to provide power to the current sensing unit 104.

The housing 108 houses the current sensing unit 104 and the power source 106. In a preferred embodiment of the present invention the housing 108 maintains the position of the current sensing unit 104 and the power source 106 to a fixed position in proximity to the electrical cord. The housing 108 covers the current sensing unit 104 and the power source 106 from forces that may disturb their position or working.

In another preferred embodiment of the present invention, the apparatus 100 further includes a visual display unit 116 for displaying the computed value of the current flowing in the electrical cord connected to the computing unit 112 and the power source 106. An example of a visual display unit 116 includes but is not limited to LED display, LCD display, OLED display etc.

In another preferred embodiment of the present invention, the apparatus 100 further includes a notification unit 118 connected to the current sensing unit 104 for producing notifications if the computed value of the current flowing exceeds a pre-stored reference current value. The pre-stored reference current value is explained in detailed in conjunction with FIG. 3 of the present invention.

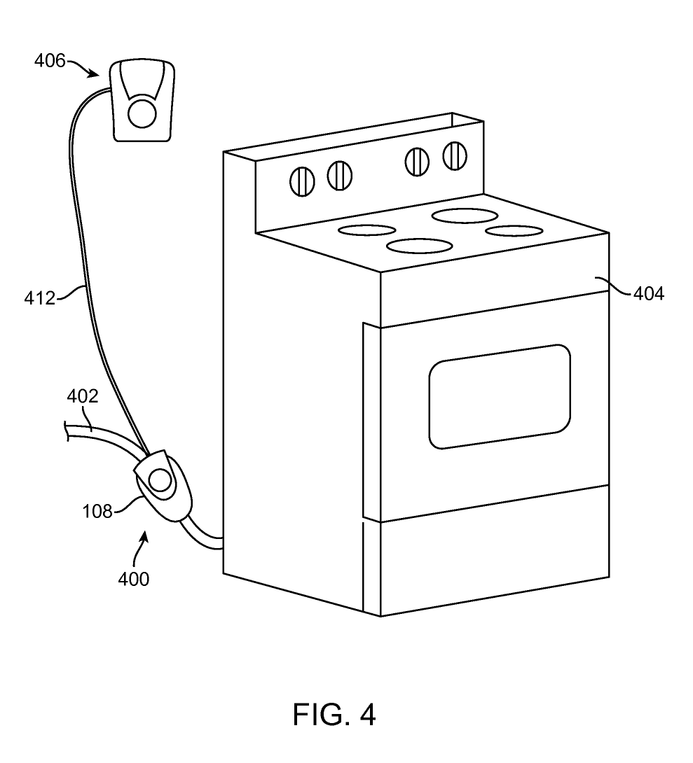

Examples of notifications produced by the notification unit 118 includes but is not limited to a visual notification, an audio notification and a combination of both visual and audio notification. An exemplary embodiment of the notification unit 118 is explained in detail in conjunction with FIG. 4 of the present invention. The notification unit 118 may include a LED unit to emit visual notifications and a speaker to generate audio notifications.

In a preferred embodiment of the present invention, the computing unit 112 may be programmed to send notifications at regular time intervals till the current flow is less than the pre-stored current value in the electrical cord. In a preferred embodiment of the present invention, the time interval for producing either audio or visual notifications is after every ten minutes.

In another preferred embodiment of the present invention, the current sensing unit 104 further includes a transmitter 124 to transmit the computed value of the current flowing in the electrical cord to the external device 114. Examples of external device 114 includes but not limited to a smart phone, laptops, computers etc. In a preferred embodiment of the present invention, the mode of transmission of computed value from the transmitter 124 to the external device 114 is wireless. Examples of transmitters 124 include but are not limited to physical transmitter, electronic transmitter, biological transmitter, broadcast transmitter etc.

In another preferred embodiment of the present invention, the apparatus 100 further includes a reset button 120 for controlling the programs stored in the computing unit 112. The reset button 120 may be attached either to the notification unit 118 or the current sensing unit 104.

In another preferred embodiment of the present invention, the apparatus 100 further includes a power button 122 for operating the power source 106. The power button 122 either turns the power source on or off the power source 106 depending upon the requirement.

FIG. 2 illustrates a perspective view of the apparatus 200 attached to the electrical cord 202 in an exemplary embodiment of the present invention. In an exemplary embodiment, the electrical cord 202 includes four wires 204 such as first hot 204a, second hot wire 204b, ground wire 204c and neutral wire 204d. The apparatus 200 having a 3-axis sensor (not shown in FIG. 2) for measuring the strength and orientation of the magnetic field in the vicinity of the electrical cord 202. In a preferred embodiment of the present invention, the apparatus 200 includes one or more attachment units 206 for attaching the housing 108 with the electrical cord 202. Examples of attachment units 206 include but not limited to straps, tapes, coils etc.

For example, in an electrical cord, the A/C current transmits to the electrical appliance and returns from the electrical appliance through the same cord. The transmission of the current through the same cord creates a magnetic field of equal and opposite strength. Therefore the magnetic fields tend to cancel each other out in the electrical cord. However, the cancellation of these magnetic fields does not occur perfectly and creates small temporal variations in the magnetic field surrounding the electrical cord. The three or more axis sensor detects the generated temporal variations in the magnetic field surrounding the electrical cord 202.

FIG. 3 illustrates a graphical representation of detection of the current flowing in the electrical cord. In a preferred embodiment of the present invention, the computing unit is programmed with a reference current value in the form of ellipsoidal graph, where points in a graphical representation take the shape of an ellipse. Typically the computing unit computes sample points such as 302a and 302b for computing the value of the current, when the sample points such as 302a and 302b are plotted in three dimensions, shows the presence of the current flowing in the electrical cord if the sample points take the shape of an ellipse. Further the computing unit then computes the current flow in the electrical cord by taking samples at pre-defined time intervals.

If the distance 306 between the sample points and the reference value is small, then the pattern is a “match” to the ellipse and therefore current is flowing through the electrical cord. If the pattern is not matching to the ellipse and the graph of sample points are very close to a single point then it is clear that no current is flowing through the electrical cord.

The value of the current flowing in the electrical cord may be calculated by programming various set of instructions in the computing unit. In a preferred embodiment of the present invention, the computing unit is programmed to execute at least one of: a low power mode for sampling the sets of electric current at low rate of frequency; a high power mode for sampling the sets of electric current at high rate of frequency; and a switch mode to switch from low power mode to high power mode for sampling the sets of electric current at high rate of frequency.

Following are some examples of set of instructions for calculating the current flowing in the electrical cord:

### Set of Instructions for High Power Mode

The processor executes the instructions stored in high power mode for computing values in between at least two electrical signals and comparing it to a reference value. A sample set of magnetic field magnitude and orientation measures is taken and stored. The processor computes the average of these samples (the “center point” 304). Further, the processor computes the difference in between each sample point and the center point. The maximum and minimum differences are noted for the sample set (the range). If the calculated range is within a specified percentage (e.g. 35%) of a stored reference current value, then the set of instructions concludes that current is likely to be flowing through the electrical cord. The computing unit then generates a notification signal. If the computing unit concludes that the current has ceased flowing through the electrical cord then the computing unit will switch from high power mode to low power mode.

### Set of Instructions for Low Power Mode

The processor executes the instructions stored for computing the values in between at least two electrical signals and comparing it to a reference value. A sample set of magnetic field magnitude and orientation measures is taken and stored. The processor computes the average of these samples (the “center point”). Further, the distance between each sample point and (the “center point”) is taken and averaged in order to calculate the average distance from the center point. If this average is greater than the stored reference value, then the algorithm concludes that current is likely to be flowing through the electrical cord. If the computing unit computes that the average is greater than the stored reference value then algorithm may also switch from the low power mode to the high power mode.

The variations in the magnetic field created around the electrical cord detected by using the aforementioned set of instructions are used to approximate whether the graph is in the shape of an ellipse. The set of instructions successfully identifies the load on an electrical appliance and distinguishes the varying magnetic fields of that load from other types of magnetic phenomena or interference present in many home or business environments, for example the earth's magnetic field, magnets or changes in orientation.

### Set of Instructions in an First Exemplary Embodiment

In another preferred embodiment of the present invention the various sets of instructions retrieve the detected measurements from the three or more axis sensor for measuring the strength of temporal fluctuations in the magnetic field and further determines the degree to which these temporal fluctuations are similar to the ellipse plotted in three dimensions.

Preferably, the set of instructions collects magnetic field strength data for x, y, z axis using a magnetometer sensor at a low sample rate and calculates the mean deviation among a group of sampled points. Further the stored instructions perform the conditional operation such as if the sample points exceeds a threshold value then the set of instructions collects the additional magnetic field strength data for x, y, z axis using a magnetometer at a high sample rate otherwise repeat the process of collecting the magnetic field strength data for x, y, z axis using the magnetometer at a low sample rate.

Further the set of instructions calculates the mean deviation among a new set of sampled data points collected at the high sample rate. If the sample set exceeds a threshold, then a further calculation is performed to access the similarity between the collected data points at high sample rate and the ellipse formed due to the mean deviation of the sampled data points. The range of sample distances from the average data points is calculated and compared to the previous sample sets. If the range does not exceed a threshold then it is presumed that NC current is flowing through the electric cord.

### Set of instructions in Second Exemplary Embodiment

Problem: There are circumstances where the appliance's status may be “on”, yet little, if any, power is being consumed. This is common for electrical appliances such as stoves, coffee makers, and microwaves which cycle power consumption on and off periodically (for example to control the temperature of a heating element) during their use.

Solution: In the aforementioned cases, the set of instructions attempt to establish, whether a device remains on, even when no current is presently being detected. The estimate is accomplished by measuring the last time that current was detected in the electrical appliance, and using that to calculate an elapsed time since a detection of current was last made. If the elapsed time exceeds a threshold reference value for the appliance, then the appliance is judged to be off (e.g. it has timed out). And if the elapsed time is less than a threshold reference value for the appliance, then the appliance is judged to be on. If the type of appliance (e.g. stove, microwave, coffee maker) is known in advance, the threshold reference value may be a constant stored value. If the type of appliance is unknown, then the threshold reference value may be generated dynamically. The dynamic reference value is calculated by observing the typical time periods between on and off cycles of the appliance during use, the observed time period value is then increased (in order to accommodate elapsed times that, in future, may be greater than the observed values), and then the calculated result is used as the threshold reference value.

FIG. 4 illustrates a perspective view of the housing 108 attached to the electrical cord 402 of an electrical appliance 404 and transmitting the current value to the notification unit 406 in an exemplary embodiment of the present invention.

In another preferred embodiment of the present invention, the apparatus 400 includes an attachment wire 412 to connect the notification unit 406 to the housing 108. The notification unit 406 then produces notifications as per the commands of the computing unit (not shown in FIG. 4).

The foregoing discussion discloses and describes merely exemplary embodiments of the present invention. One skilled in the art will readily recognize from such discussion and from the accompanying drawings that various changes, modifications and variations can be made therein without departing from the spirit and scope of the invention.

1. An apparatus for sensing current flowing through at least one electric cord of an electric appliance, the electric cord comprising at least two current carrying wires said apparatus comprising:
a current sensing unit arranged proximate to at least one electric cord, said current sensing unit comprising:
at least one sensor of three or more axis operative to detect the changes in magnitude and orientation of magnetic field caused by the current flowing through in at least two current carrying wires of the electric cord for generating an electrical signal; and
a computing unit programmed to compute the value of current flowing from the generated electrical signal.

2. The apparatus according to claim 1 further comprising a visual display unit connected to said computing unit and said power source to display the computed value of the current flowing in the electrical cord.

3. The apparatus according to claim 1 further comprising a notification unit connected to said current sensing unit and said power source for producing notifications if the computed value of the current flowing exceeds a pre-stored reference current value.

4. The apparatus according to claim 1 further comprising one or more attachment units to attach said housing with at least one of the electrical cord of the electrical appliance.

5. The apparatus according to claim 1 wherein said current sensing unit further comprising a transmitter to transmit the computed value of the current flowing in the electrical cord to an external device.

6. The apparatus according to claim 1 further comprising a reset button to control programs stored in said computing unit.

7. The apparatus according to claim 1 further comprising a power button for operating said power source.

8. The apparatus according to claim 3 wherein said notification unit produces at least one of:
a visual notification;
an audio notification; and
a combination of both visual and audio notification.

9. The apparatus according to claim 3 wherein said pre-stored current reference value are points plotted in ellipsoidal graph, wherein said computing unit plots the computed current values to measure the differences with the ellipsoidal graph points, wherein further said notification unit produces notification signals if the computed value is below the pre-stored current reference value.

10. The apparatus according to claim 1, wherein said computing unit further programmed to execute at least one of:
a low power mode for sampling the sets of electric current at low rate of frequency;
a high power mode for sampling the sets of electric current at high rate of frequency; and
a switch mode to switch from low power mode to high power mode for sampling the sets of electric current at high rate of frequency.

11. The apparatus according to claim 1 further comprising a power source operative to power said current sensing unit.

12. The apparatus according to claim 1 further comprising a housing operative to house said current sensing unit and said power source.

13. The apparatus according to claim 1 wherein said three or more axis sensor is a 3-axis magnetometer.
